(19) United States
(12) Patent Application Publication
(10) Pub. No.: US 2008/0200032 A1
(43) Pub. Date: Aug. 21, 2008

(54) POLISHING METHOD OF SEMICONDUCTOR SUBSTRATE

(75) Inventors: Toranosuke ASHIZAWA, Ibaraki-shi (JP); Masaya NISHIYAMA, Ibaraki (JP); Ara PHILIPOSSIAN, Tucson, AZ (US); Yun ZHUANG, Tucson, AZ (US); Yasa Adi SAMPURNO, Tucson, AZ (US); Fransisca SUDARGHO, Tucson, AZ (US)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: HITACHI CHEMICAL CO., LTD., Tokyo (JP); ARACA INCORPORATED, Tucson, AZ (US)

(21) Appl. No.: 12/033,381

(22) Filed: Feb. 19, 2008

Related U.S. Application Data
(60) Provisional application No. 60/902,056, filed on Feb. 20, 2007.
(60) Provisional application No. 60/943,407, filed on Jun. 12, 2007.

(51) Int. Cl. H01L 21/302

(52) U.S. Cl. 438/690; 257/E21.214

(57) ABSTRACT

The present invention relates to a method of polishing a semiconductor substrate, comprising pressing a semiconductor substrate having a film to be polished that is held by a carrier onto a polishing cloth fixed on a revolving polishing table and supplying a polishing slurry to the space between the polishing cloth and the semiconductor substrate, wherein the end point of polishing is determined according to the change in the friction coefficient while the friction coefficient between the semiconductor substrate and the polishing cloth is measured. According to the present invention it is possible to measure friction coefficient accurately in polishing a semiconductor substrate and use the change thereof to determine the end point of polishing.

### BACKGROUND OF THE INVENTION

1. Field of the Invention

The present invention relates to a method of determining the end point of polishing in the step of chemical mechanical polishing for surface smoothening in production of a semiconductor device.

2. Description of the Prior Art

Currently under research and development are processing methods for improvement in density and miniaturization in production of ULSI semiconductor devices. One of the methods, CMP (chemical mechanical polishing) technology, is now a technology essential in production of semiconductor devices, for example, for smoothening of interlayer dielectric film, forming a shallow trench device isolation, forming a plug and forming an embedded metal wiring.

Generally in chemical mechanical polishing, a polishing cloth is first fixed on a rotary polishing table of a polishing machine, while an irregular-surfaced semiconductor substrate is fixed on a carrier. Chemical mechanical polishing is performed by pressing the carrier onto the revolving polishing cloth, while a polishing slurry is supplied to the polishing cloth. Irregularity on the substrate present before polishing is eliminated by chemical mechanical polishing, and the substrate surface is smoothened. The polishing should be terminated rapidly after the surface is smoothened for uniformizing the removal amount.

A time management method of keeping the polishing period constant and an endpoint detection method of detecting the polishing end point have been used for making the thickness of the surface-smoothened film constant after polishing of a semiconductor substrate, but the endpoint detection method is advantageous because of its easiness of management. In polishing a semiconductor substrate carrying an integrated circuit formed, a film different from the polishing film exposed on the surface before polishing often becomes exposed during polishing. In such a case, the shearing force changes, according to the material used for the polished film, and methods of using such a shearing force in the endpoint detection method are disclosed, for example, in U.S. Pat. No. 5,036,015 and Japanese Patent Application Laid-Open No. 8-197417. Endpoint detection leads to improvement in the reproducibility of polishing amount.

### SUMMARY OF THE INVENTION

In the polishing method above, the shearing force gives a torque on the polishing table, and a load is applied to the polishing table. Thus, it is possible to determine the shearing force by measuring the electric current of the motor driving the polishing table. The shearing force F, the torque Tq generated on the polishing table, and the distance r between the position of the shearing force applied to the polishing table and the rotational center of the polishing table have the relationship: Tq=F×r. However, the position r of the semiconductor substrate on the polishing table is variable as it moves during polishing, and thus, the shearing force F cannot be determined only by the motor current. As described above, there is still no method of directly measuring the shearing force generated between a revolving semiconductor substrate and a polishing cloth that can be performed easily industrially.

For example, when conditioning, i.e., surface roughening of the polishing cloth, is performed simultaneously with polishing, a torque is applied to the motor driving the polishing table, and the motor current changes. In addition, a load of the polishing table itself is applied to the motor, and contribution of the shearing force between the semiconductor substrate and the polishing cloth in the motor torque becomes relatively smaller. Thus, determination of the shearing force between semiconductor substrate and polishing cloth from the motor current leads to expansion of error.

An object of the present invention is to provide a polishing method of measuring the friction coefficient during polishing of a semiconductor substrate and using the change thereof in determining the polishing end point.

The present invention relates to (1) a method of polishing a semiconductor substrate, comprising pressing a semiconductor substrate having a film to be polished that is held by a carrier onto a polishing cloth fixed on a revolving polishing table and supplying a polishing slurry to the space between the polishing cloth and the semiconductor substrate, wherein the end point of polishing is determined according to the change in the friction coefficient while the friction coefficient between the semiconductor substrate and the polishing cloth is measured.

The present invention also relates to (2) the method of polishing a semiconductor substrate according to (1), wherein the friction coefficient is determined from the shearing force applied to the polishing cloth and the semiconductor substrate by polishing.

The present invention also relates to (3) the method of polishing a semiconductor substrate according to (2), wherein the shearing force is detected as two forces mutually rectangular to each other in the horizontal direction transmitted to the carrier or polishing table.

The present invention also relates to (4) the method of polishing a semiconductor substrate according to (2) or (3), wherein the end point of polishing is identified by extracting frequency components by fast Fourier transformation of the shearing force and determining the intensity change of each extracted frequency component.

The present invention also relates to (5) the method of polishing a semiconductor substrate according to any one of (1) to (4), comprising exposing a different film to be polished during polishing, wherein the ratio of the polishing rate RR2 of the newly exposed film to be polished to the polishing rate RR1 of the film exposed on the semiconductor substrate surface immediately therebefore, RR1/RR2, is 10 or more.

The present invention also relates to (6) the method of polishing a semiconductor substrate according to any one of (1) to (5), wherein the surface of the film to be polished is irregular when polishing is initiated.

The present invention also relates to (7) the method of polishing a semiconductor substrate according to any one of (1) to (6), wherein a polishing slurry containing cerium oxide particles and ammonium polyacrylate or an ammonium acrylate copolymer is used.

The present invention also relates to (8) the method of polishing a semiconductor substrate according to any one of (1) to (7), wherein the film to be polished contains silicon oxide (SiO₂) and silicon nitride (SiN).

It is possible to determine the polishing end point easily and prevent excessive or insufficient polishing, according to the present invention. In particular, it is possible to terminate polishing reliably after exposure of the silicon nitride (SiN) film in surface-smoothening a dielectric film for shallow trench isolation.

### BRIEF DESCRIPTION OF THE DRAWINGS

FIG. 1A is a schematic side view illustrating an example of the method of measuring shearing force according to the present invention.

FIG. 1B is a schematic plain view illustrating an example of the method of measuring shearing force according to the present invention.

FIG. 2 is a sectional view illustrating a semiconductor substrate of a shallow trench isolation film having a test pattern formed on the surface used in Examples of the present invention.

FIG. 3 is a graph showing the change over time in the shearing force obtained in Examples of the present invention.

FIG. 4A, FIG. 4B and FIG. 4C show examples of the spectra after fast Fourier transformation (FFT) of the shearing force obtained in an Example of the present invention.

### BEST MODE FOR CARRYING OUT THE INVENTION

In the method of polishing a semiconductor substrate according to the present invention, a semiconductor substrate having a polishing film on the surface is polished, while it is pressed on a polishing cloth fixed on a revolving polishing table. A polishing slurry is supplied to the space between the polishing cloth and the semiconductor substrate at the same time. The semiconductor substrate may be held by a carrier, and the carrier may be rotated by a driving unit, separately from the polishing table.

In the polishing method according to the present invention, the end point of polishing is determined from the change in the coefficient of friction COF between the substrate and polishing cloth during polishing. The coefficient of friction COF between the substrate and polishing cloth during polishing is represented by the ratio of the shearing force Fshear applied to the substrate and the polishing cloth to the load applied to the substrate Fnormal (Fshear/Fnormal). Fnormal is a value in proportion to the load applied to the carrier, and thus, the coefficient of friction COF is in proportion to the shearing force Fshear when Fnormal is constant.

In directly determining the shearing force Fshear applied to the substrate and the polishing cloth (hereinafter, referred to also as shearing force), a force in the horizontal direction generated on the polishing table or the carrier may be measured.

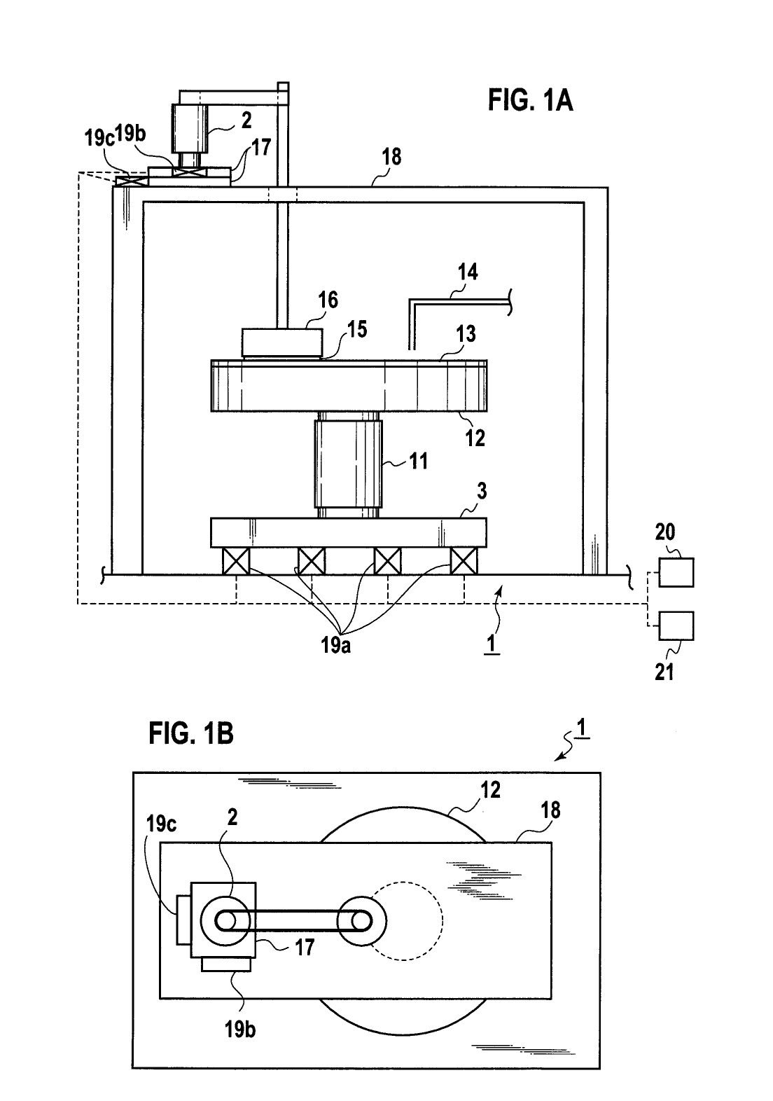

(1) The method of determining the coefficient of friction COF by the force in the horizontal direction generated on the carrier and the load applied via the carrier onto the polishing table will be described with reference to drawings. FIG. 1A is a schematic side view illustrating the measuring method according to the present invention. FIG. 1B is a schematic plain view illustrating an example of the method of measuring shearing force according to the present invention. A polishing cloth 13 is fixed on a polishing table 12, and the polishing table 12 (diameter: 500 mm) is rotated, as driven by a drive motor 11. A polishing slurry is supplied through a polishing slurry-supplying tube 14. The polishing table 12 and the drive motor 11 are fixed on a stand 3, and stored in a polishing machine 1 via load cells 19a. A semiconductor substrate 15 is fixed on the carrier 16 and pressed downward by the carrier 16. A motor 2 rotating the carrier 16 and its slide plate 17 movable only in one direction are mounted on a stand 18 mechanically separated from the polishing table 12. A pressure (load) applied from the carrier 16 in the vertical direction is transmitted to the polishing table 12, the stand 3, and load cells 19a. The load cells 19a detect the pressure in the vertical direction, and the electrical signals generated in the load cells 19a are transmitted to a recorder 20 and fast Fourier transform device (FFT 21).

The center position of the semiconductor substrate 15 is fixed by the carrier 16 and is placed eccentric on the polishing table 12, and thus, a shearing force in the horizontal direction is applied by friction with the polishing cloth 13. The shearing force generated on the semiconductor substrate 15 is transmitted, through the carrier 16, motor 2, and slide plate 17, to the load cells 19b and 19c. The load cell 19b detects the depth-direction component of shearing force, while the load cell 19c the width-direction component of shearing force; and these components are transmitted to the recorder 20 and FFT21.

The ratio Fshear/Fnormal and the coefficient of friction COF are calculated from the shearing force in combination of these two components and the load in the vertical direction.

(2) The method of measuring the force in the horizontal direction generated on the polishing table is the same in principle as the method (1). The carrier and the driving unit are fixed on a stand separated from the polishing machine containing a polishing table, and the shearing force generated on the carrier is designed not to be transmitted to the polishing machine. The polishing machine is mounted via bearings on a stand, as it is allowed to move freely in a straight-line direction. When the substrate becomes in contact with the polishing cloth, a force in the horizontal direction is generated onto the polishing table by the shearing force, and the travelling distance is detected by strain gauge or the force is detected by the load cell as voltage. The voltage signal thus obtained is sent to a signal-processing unit, where it is processed.

Although the carrier presses the polishing table downward in FIGS. 1A and 1B, the present invention may be applied similarly to a polishing machine wherein the carrier and the polishing table are placed upside-down.

The shearing force is measured in real time, and all components including direct-current to high-frequency components are determined according to the frequency characteristics of the load cell or strain gauge. The friction coefficient obtained from the shearing force also includes a high-frequency component, and it is possible to analyze the friction coefficient at each frequency by fast Fourier transformation (FFT) thereof.

The friction coefficient depends on the physical properties of the film to be polished, the polishing slurry, and the polishing cloth. Conditioning by using a dresser may be needed for keeping the polishing cloth surface state constant, but the conditioning is performed at least during polishing or after polishing. According to the present invention, it is possible to detect the shearing force between the semiconductor substrate and the polishing cloth with smaller error, because there is no influence on the friction coefficient between semiconductor substrate and polishing cloth even when conditioning is performed simultaneously with polishing.

When there is irregularity on the surface of the film to be polished, the load concentrates on the raised regions. The area of concentrated load widens, as the surface irregularity is reduced by progress of polishing, and the load is applied uniformly on the entire semiconductor substrate surface after the surface is smoothened completely. The measured shearing force varies by the change of the area exposed to concentrated load by surface smoothening by polishing, and the polishing end point can be determined by using the change.

When the shearing force at each frequency is determined by fast Fourier transformation of the shearing force, the maximum (peak) intensity appears at a particular frequency. The peak intensity varies in proportion to the irregularity, and thus, it is possible to determine the polishing end point also by using the change in the peak intensity. The peak frequency, which is influenced by the shape, dimension of the irregularity and the polishing condition, is determined separately for each semiconductor substrate produced.

For example, when a different film to be polished is exposed during polishing as in shallow trench isolation, exposure of the new film to be polished leads to change of the friction coefficient. Silicon oxide (SiO₂) is used as the separation film and silicon nitride (SiN) as the stopper film during shallow trench isolation, and polishing is terminated when SiN is exposed on the entire surface of raised region. SiN is more resistant to polishing than SiO₂ and thus suitable as the stopper film. The friction coefficient of a semiconductor substrate surface is lower when SiN is exposed than when SiO₂ is exposed on the surface. If the present invention is applied to shallow trench isolation, SiN exposure leads to decrease in friction coefficient, and thus, the endpoint is detected more definitely when the polishing method according to the present invention is applied. Thus, exposure of a different polishing film during polishing leads to change in friction coefficient, which is favorable for detection of polishing endpoint.

In the embodiment above of a new polishing film being exposed during the polishing, the change in friction coefficient when a different polishing film is newly exposed becomes greater, if the polishing rates of respective polishing films are different from each other significantly. For that reason, when a newly polishing film is exposed, the ratio of the polishing rate RR1 of the film to be polished that was exposed on the semiconductor substrate surface immediately before to the polishing rate RR2 of the newly exposed film to be polished (RR1/RR2) is preferably larger, and a ratio RR1/RR2 of 10 or more is preferable for increasing the change in friction coefficient.

For example, increase in the ratio of the polishing rate ratio of SiO₂ to SiN during polishing of shallow trench isolation is advantageous in that it is possible to terminate polishing immediately after exposure of the entire stopper SiN. It is possible to raise the polishing rate ratio of SiO₂ to SiN to 10 or more, by using a polishing slurry containing cerium oxide particles and an ammonium polyacrylate or an ammonium acrylate copolymer. Silica particles have been used widely for polishing semiconductor products, but the polishing rate ratio of SiO₂ to SiN is approximately 3, when silica particles are used. Although it is possible to perform the method of polishing a semiconductor substrate according to the present invention by using silica particles, use of a polishing slurry containing cerium oxide particles and an ammonium polyacrylate or ammonium acrylate copolymer is desirable for shallow trench isolation, because it leads to increase of the change in friction coefficient when a new SiN film is exposed.

FIG. 3 shows the change in shearing force over time obtained by polishing a film having surface irregularity and a different kind of film inside by the method shown in FIGS. 1A and 1B. The coefficient of friction COF is represented by Fshear/Fnormal, and in such a case, the load Fnormal is a value in proportion to the pressure applied to the carrier. Thus, COF is in proportion to the shearing force Fshear. The change in shearing force Fshear over time may be divided into three ranges. In the first range from initiation of polishing to time T1, the shearing force is low and almost constant. In the second range from time T1 to T2, the shearing force increases. In the third range after time T2, the shearing force declines slightly. The change may be construed in the following way: In the first range, irregularity on the film to be polished is gradually eliminated, but the contact area between the raised region and the polishing cloth is kept almost constant. In the second range, surface irregularity of the film to be polished is almost eliminated, and the contact area between the polishing cloth and the raised region increases. Increase of contact area leads to increase of shearing force. In the third range, a different kind of film begins to appear.

The different kind of film is exposed completely on the surface at time T3 in the third range. The time T3 represents the end point of polishing; in determining time T3 from the change in shearing force, the time T2 when the shearing force changes from climbing to constant or declining is calculated from the differential of the shearing force during polishing. The period from time T2 to T3 is a period needed for making the exposure state of the different kind of film, thickness of the different kind of film, level difference and others satisfy the requirements in production control of semiconductor integrated circuits, which is determined by preliminary polishing, and may be set to a certain period. Thus, the time T3 is a certain period after the time T2.

The polishing condition is kept constant in the embodiments above, but, for example, the load applied to the substrate or the rotational frequency of the surface plate or substrate may be altered. Even in such a case, it is possible to determine the time T2 in FIG. 3 from the shearing force, because the polishing condition is changed only about three times at most during polishing of one substrate and the pressure (load) applied to the substrate does not change from moment to moment.

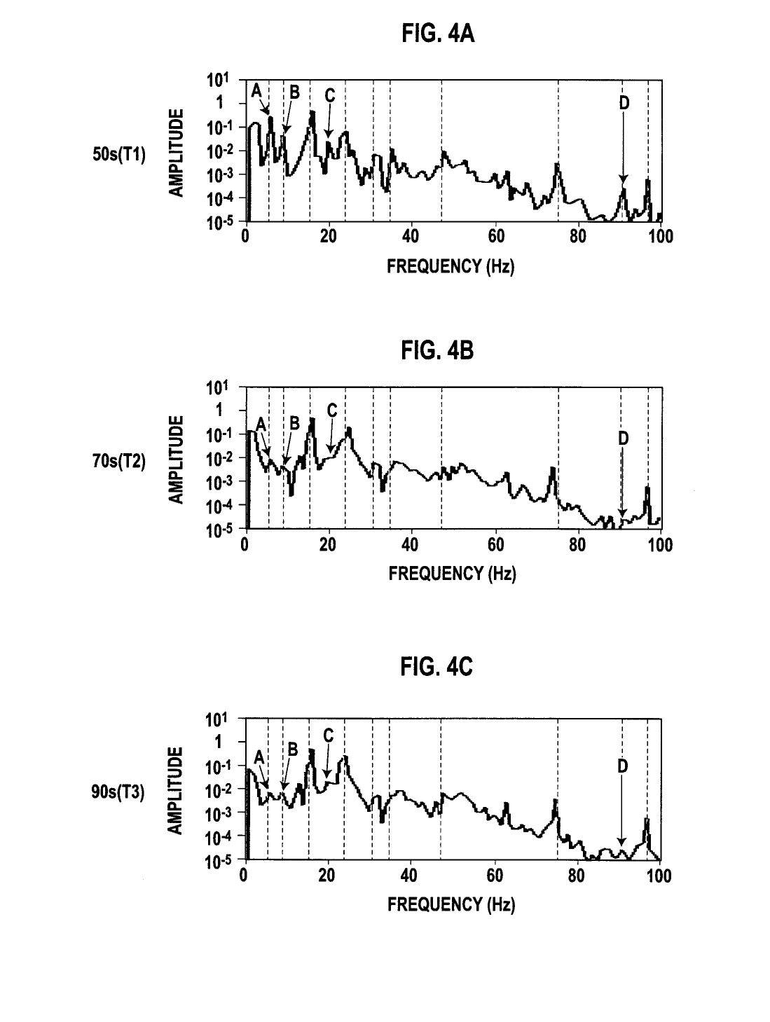

Results (spectra) obtained by fast Fourier transformation of the shearing forces at T1, T2, and T3 in FIG. 3 are shown in FIGS. 4A, 4B and 4C. There are many peaks observed in FIGS. 4A, 4B and 4C. All of the peaks A, B, C, and D observed at time T1 disappear mostly at time T2. The spectrum at time T3 is almost the same as that at time T2. As obvious from FIGS. 4A, 4B and 4C, the peak intensity of the peaks A, B, C, and D changes drastically at time T2, and thus, the time of change represents T2. T3 is the time separated by a certain period from the time T2, similarly as defined in FIG. 3 above.

The polishing method according to the present invention can also be used in the conductor polishing step and in the barrier film polishing step in embedding metal wiring in semiconductor devices.

### EXAMPLES

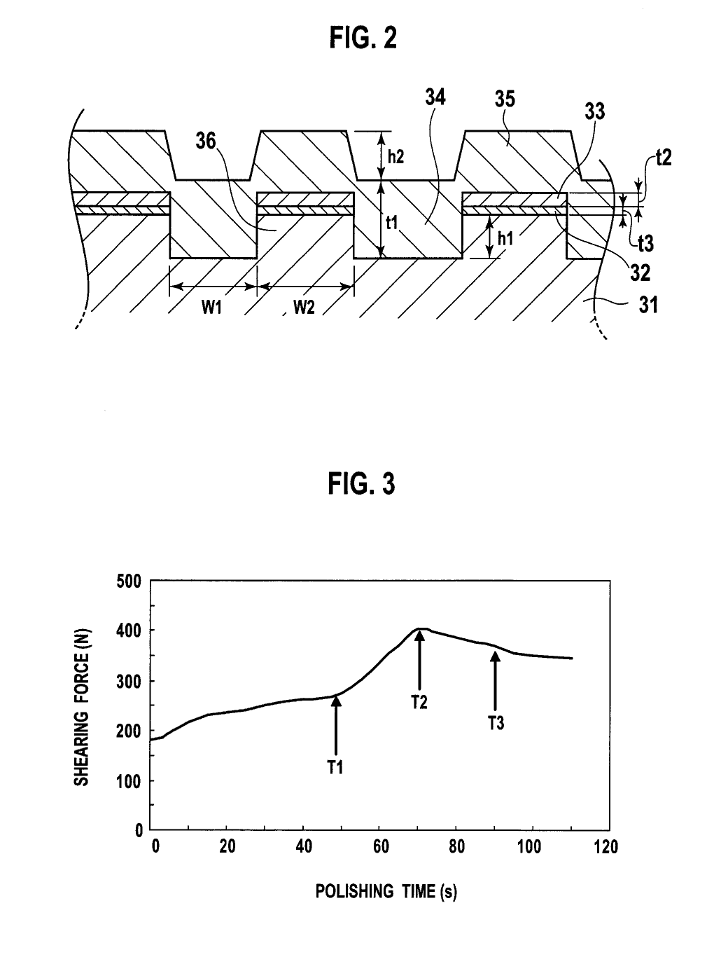

Hereinafter, the present invention will be described with reference to Examples. FIG. 1A is a schematic side view illustrating the shearing force measurement method used in an example of the present invention. FIG. 1B is a schematic plain view illustrating the shearing force measurement method used in an example of the present invention. A polishing cloth 13 is fixed on a polishing table 12, and the polishing table 12 (diameter: 500 mm) is rotated, as driven by a drive motor 11. The polishing table 12 and the drive motor 11 are fixed on a stand 3, and stored in a polishing machine 1 via load cells 19a. FIG. 2 is a cross-sectional view of a semiconductor substrate carrying a test pattern for shallow trench isolation film on the surface. The semiconductor substrate 15 is fixed on a carrier 16 and pressed downward by the carrier 16. A motor 2 rotating the carrier 16 and its slide plate 17 movable only in one direction are mounted on a stand 18, which is mechanically separated from the polishing table 12. A pressure applied from the carrier 16 in the vertical direction is transmitted to the polishing table 12, the stand 3, and load cells 19a. The load cells 19a detect the pressure in the vertical direction, and the electrical signals generated in the load cells 19a are transmitted to a recorder 20 and FFT 21.

The center position of the semiconductor substrate 15 is fixed by the carrier 16 and is placed eccentric on the polishing table 12, and thus, a shearing force in the horizontal direction is applied by friction with the polishing cloth 13. The shearing force generated on the semiconductor substrate 15 is transmitted, through the carrier 16, motor 2, and slide plate 17, to the load cells 19b and 19c. The load cell 19b detects the depth-direction component of shearing force, while the load cell 19c the width-direction component of shearing force, and these components are transmitted to the recorder 20 and FFT21.

A test pattern having the cross-sectional structure shown in FIG. 2 was used for evaluation of the CMP for shallow trench isolation. A pad oxide layer 32 and a SiN stopper film 33 were formed one by one on a silicon substrate 31, and trenches 34 were formed thereon. An HDP SiO₂ film 35 was formed thereon, and the product was used as the test pattern wafer for evaluation of CMP. The depth of the trench h1 was 400 nm; the stopper layer thickness t2 was 110 nm; the thickness of the pad oxide layer t3, 12.5 nm, and the thickness of the HDP SiO₂ layer thickness t1, 670 nm. The width of the shallow trench isolation w1 was 50 μm, and the width of the active element 36, w2 was 50 μm. The difference in surface level before CMP h2 was 542 nm. IC-1000/Suba400 laminate pad manufactured by Rohm and Haas having concentric grooves processed on the surface was used as the polishing cloth 13. A dresser (not shown in Figure) was used for making the polishing cloth surface uniform. The dresser having a diameter of 100 mm carries #100 grit diamond particles. A dispersion of 1 wt % cerium oxide particles (volumetric median diameter (d50): 0.25 μm, d99: 0.67 μm) and 0.3 wt % ammonium polyacrylate (weight-average molecular weight Mw, as determined by gel permeation measurement: 8000) in purified water at pH 5.0 was used as the polishing slurry supplied from the polishing slurry-supplying tube 14. An analyzer LA-920 manufactured by Horiba, Ltd. was used for measurement of the particle size distribution of the polishing slurry, under the condition of a refractive index of 2.138 and an absorption coefficient of 0. The value d99 represents a particle diameter at an accumulated total volume of 99% when the volumes of particles are measured from the particle smallest in volume.

The operational condition of the polishing machine is as follows: polishing table rotational frequency: 93 min⁻¹, carrier rotational frequency: 87 min⁻¹, carrier pressure: 22 kPa, dresser load: 26N, and dresser rotational frequency: 30 min⁻¹. The dressing was performed simultaneously during polishing. The amount of the polishing slurry supplied was 200 ml/min.

FIG. 3 shows the change of the shearing force obtained over time. FIG. 3 showed that the time T2 when the shearing force Fshear is maximal was 70 seconds. The thicknesses of respective films and the level differences before polishing and 70, 80, 90, 100, and 110 seconds after polishing were as follows:

T=0 (before polishing)

Thickness of stopper layer (SiN) t2: 101 nm

Thickness of dent layer (SiO₂) t1: 678 nm

Level difference h2: 542 nm

No stopper film exposed

T=70 s (T2)

Thickness of stopper layer (SiN) t2: 101 nm

Thickness of dent layer (SiO₂) t1: 540 nm

Level difference h2: 4 nm

Part of stopper film exposed

T=80 s (T2+10 S)

Thickness of stopper layer (SiN) t2: 100 nm

Thickness of dent layer (SiO₂) t1: 522 nm

Level difference h2: 18 nm

Part of stopper film exposed

T=90 s (T2+20 s)

Thickness of stopper layer (SiN) t2: 101 nm

Thickness of dent layer (SiO₂) t1: 501 nm

Level difference h2: 39 nm

Entire stopper film exposed

T=100 s (T2+30 s)

Thickness of stopper layer (SiN) t2: 101 nm

Thickness of dent layer (SiO₂) t1: 481 nm

Level difference h2: 62 nm

Entire stopper film exposed

T=110 s (over-polishing)

Thickness of stopper layer (SiN) t2: 103 nm

Thickness of dent layer (SiO₂) t1: 450 nm

Level difference h2: 94 nm

Entire stopper film exposed

Spectra obtained by fast Fourier transformation of the shearing force are shown in FIGS. 4A, 4B and 4C. The frequency (Hz) is plotted on the abscissa and shearing force intensity ratio (logarithm) on the ordinate in FIGS. 4A, 4B and 4C. Ten or more peaks are observed in the frequency range of 5 to 100 Hz, 50 seconds after initiation of polishing Start (T1) as shown in FIG. 4A. Observation of the change in intensity of the peak A (around 5 Hz), peak B (around 7 Hz), peak C (around 20 Hz), and peak D (around 90 Hz) revealed that the four lines were all distinctive after 50 seconds (T1). The four lines disappeared mostly after 70 seconds (T2) as shown in FIG. 4B. Similarly, the four lines disappeared mostly after 90 seconds (T3) as shown in FIG. 4C. Therefore, T2 can be identified easily as the time of the drastic change in intensity of the peak A, B, C, or D.

Favorably in the example, all stopper film was exposed in 90 seconds, and the level difference was small at 39 nm. When polishing was continued for up to 110 seconds, the level difference expanded to 94 nm. When the same test pattern is polished continuously in the condition of the Example, the polishing end point T3 is found to be desirably 20 seconds after the time T2 (70 seconds) when the shearing force Fshear is largest. It is possible to determine the maximum point T2 of each polishing substrate, and thus, to reduce the fluctuation of the polishing end point of each substrate even if there is some dispersion.

The polishing rates of the blanket wafers with the polishing slurry used were as follows: The polishing condition was the same as that for the test pattern polishing.

SiO₂ (plasma TEOS) film: 450 nm/min

SiN film: 8 nm/min

SiO₂/SiN polishing rate ratio: 56

The shearing force showed a tendency to decline after the time T2. It was because of gradual exposure of the SiN film, and the tendency was more distinct, especially when a polishing slurry having a high SiO₂/SiN polishing rate ratio of 10 or more was used. Thus, the position of T2 becomes more distinctive.

1. A method of polishing a semiconductor substrate, comprising pressing a semiconductor substrate having a film to be polished that is held by a carrier onto a polishing cloth fixed on a revolving polishing table and supplying a polishing slurry to the space between the polishing cloth and the semiconductor substrate, wherein the end point of polishing is determined according to the change in the friction coefficient while the friction coefficient between the semiconductor substrate and the polishing cloth is measured.

2. The method of polishing a semiconductor substrate according to claim 1, wherein the friction coefficient is determined from the shearing force applied to the polishing cloth and the semiconductor substrate by polishing.

3. The method of polishing a semiconductor substrate according to claim 2, wherein the shearing force is detected as two forces mutually rectangular to each other in the horizontal direction transmitted to the carrier or polishing table.

4. The method of polishing a semiconductor substrate according to claim 2, wherein the end point of polishing is identified by extracting frequency components by fast Fourier transformation of the shearing force and determining the intensity change of each extracted frequency component.

5. The method of polishing a semiconductor substrate according to claim 1, comprising exposing a different film to be polished during polishing, wherein the ratio of the polishing rate RR2 of the newly exposed film to be polished to the polishing rate RR1 of the film exposed on the semiconductor substrate surface immediately therebefore, RR1/RR2, is 10 or more.

6. The method of polishing a semiconductor substrate according to claim 1, wherein the surface of the film to be polished is irregular when polishing is initiated.

7. The method of polishing a semiconductor substrate according to claim 1, wherein a polishing slurry containing cerium oxide particles and ammonium polyacrylate or an ammonium acrylate copolymer is used.

8. The method of polishing a semiconductor substrate according to claim 1, wherein the film to be polished contains silicon oxide and silicon nitride.
